(19) United States
(12) Patent Application Publication
(10) Pub. No.: US 2001/0027023 A1
(43) Pub. Date: Oct. 4, 2001

(54) Organic substance removing methods, methods of producing semiconductor device, and organic substance removing apparatuses

(76) Inventor: Shigenori Ishihara, Tochigi-ken (JP)

Correspondence Address: FITZPATRICK CELLA HARPER & SCINTO, 30 ROCKEFELLER PLAZA, NEW YORK, NY, 10112, US

(21) Appl. No.: 09/779,645

(22) Filed: Feb. 9, 2001

(30) Foreign Application Priority Data
Feb. 15, 2000 (JP) 2000-036862

(51) Int. Cl. H01L 21/302

(52) U.S. Cl. 438/706

(57) ABSTRACT

An organic substance removing method is disclosed which removes an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing into a reaction chamber a gas less prone to etch an exposed surface of the substrate than the gases introduced into the reaction chamber in the first step, and generating a plasma of the gas introduced into the reaction chamber to effect a plasma processing.

### BACKGROUND OF THE INVENTION

1. Field of the Invention

The present invention relates to methods of producing a semiconductor device, and organic substance removing methods and organic substance removing apparatuses used therein and, more particularly, to methods of removing a resist having an ion-implanted region.

2. Related Background Art

The conventional processes for forming devices in a semiconductor substrate include a step of selectively etching an oxide film formed on the semiconductor substrate, a step of locally implanting ions of a substance of phosphorus, arsenic, boron, or the like into the substrate, and so on.

These steps are carried out using a photoresist consisting of an organic substance such as a photosensitive resin or the like, as a mask material.

Then, since the photoresist becomes unnecessary after completion of, for example, the selective etching, it has to be removed. For this reason, where the photoresist consists of an organic substance, it is removed by being oxidized or ashed by oxidizing action in a dry process using an oxygen plasma, oxygen radicals, ozone, or the like.

This technique utilizes the principle that, for example, inducing a discharge in oxygen gas or irradiating oxygen gas with ultraviolet light provides active oxygen and exposing the resist to the active oxygen converts the resist into gases such as water vapor, carbon dioxide gas, carbon monoxide gas, or the like by the oxidizing action of the active oxygen. This is called ashing or the like.

However, when a photoresist used as a mask material during local ion implantation is to be removed, since the photoresist has become difficult to be ashed because the implanted ions deteriorate (or affect) or harden the vicinity of the surface of the photoresist, the removal of the photoresist takes a long time.

Specifically, as described in Nuclear Instruments and Methods, B39, pp. 809-812, the cause of the implanted ions' deteriorating the vicinity of the surface of the photoresist, for example, in the case of implanting phosphorus into a cresol-novolak-based resin, is crosslinking taking place through linkage of phosphorus to phenol rings of the main chain that results from substitution thereof with methylene groups.

Further, it is known that when a deteriorated (or affected) photoresist is heated to ordinary ashing temperatures of 150° C. to 250° C., there may be occurred the so-called popping in which vapor of an organic solvent is generated in a portion not deteriorated with ions in the photoresist and causes large flake-like particles to scatter near the surface of the photoresist, and also that occurrence of the popping results in contamination of semiconductor substrates.

Further, since implanted ions become a source for forming a stable oxide difficult to vaporize by an oxidizing plasma, there are cases where after the photoresist is ashed to be removed by active species of oxygen or the like, an oxide is generated and remains on the semiconductor substrate. The remaining oxide has to be removed from the semiconductor substrate, so that it is necessary to remove the oxide with a cleaning liquid and to further dry the semiconductor substrate.

A photoresist deteriorated in the vicinity of the surface by ion implantation is normally removed by effecting ashing with a plasma of oxygen containing a carbon-fluoride-based gas typified by CF₄ to convert the ion species into volatile compounds with active species of fluorine. However, on this occasion, since a portion of the semiconductor substrate not coated with the photoresist, such as an aperture portion or the like of the photoresist, may be corroded by long-term exposure to the active species of fluorine, it is not preferable to apply this technique to fabrication processes of recent high-density semiconductor devices required to be fabricated by more precise processing.

For this reason, Japanese Journal of Applied Physics, Vol. 28, No. 10, pp. 2130-2136 describes a proposal of a two-stage processing method including a step of reducing a deteriorated layer in a photoresist surface with an active species of hydrogen less prone to corrode the underlying material, by use of, for example, the RIE (reactive ion etching) with a hydrogen plasma or a water vapor plasma to remove the deteriorated layer and a step of thereafter ashing and removing the not deteriorated portion present below the deteriorated portion by the down flow ashing using an oxygen plasma or the like.

Further, Japanese Patent Application Laid-Open No. 5-275326 describes a two-stage ashing method including a step of ashing and removing a deteriorated portion with a plasma of oxygen containing, for example, a fluorine-based gas having an action of removing the implanted ion species and a step of thereafter ashing the remaining not deteriorated resist portion with an oxygen plasma.

On the other hand, Japanese Patent Application Laid-Open No. 2000-12521 describes an ashing method of effecting ashing with a plasma of a mixed gas of a fluorine-based gas, oxygen gas and hydrogen gas.

However, in the ashing method described in Japanese Journal of Applied Physics, Vol. 28, No. 10, pp. 2130-2136, since the processing rate of ashing with the active species of hydrogen is small, decrease in processing efficiency would be a matter of concern in certain cases.

In the ashing method described in Japanese Patent Application Laid-Open No. 5-275326, since the portion not coated with the photoresist of the semiconductor substrate is corroded with the fluoride gas or active species thereof during the ashing removal of the deteriorated portion, it is not preferable to apply it to the fabrication processes of recent high-density semiconductor devices required to be processed by more precise processing.

Further, in the ashing method described in Japanese Patent Application Laid-Open No. 2000-12521, the time of exposure to the fluoride gas or active species thereof is long and the problem of corrosion has not been solved satisfactorily yet.

### SUMMARY OF THE INVENTION

An object of the present invention is to provide resist removing methods, organic substance removing methods, methods of producing a semiconductor device, and resist removing apparatuses that can remove a resist from a substrate while suppressing the corrosion of a portion of the substrate exposed out of the resist (i.e., a portion not covered with the resist of the substrate).

According to a first aspect of the present invention, there is provided an organic substance removing method of removing an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing an oxygen-containing gas into a reaction chamber without introducing a fluorine-containing gas thereinto, and generating a plasma of the gas introduced into the reaction chamber to effect a plasma processing.

According to a second aspect of the present invention, there is provided an organic substance removing method of removing an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas and an oxygen-containing gas into a reaction chamber such that the concentration of the fluorine-containing gas is not more than 0.01 vol %, and generating a plasma of the gases introduced into the reaction chamber to effect a plasma processing.

According to a third aspect of the present invention, there is provided an organic substance removing method of removing an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas, an oxygen-containing gas, and a hydrogen-containing gas into a reaction chamber such that the concentration of the fluorine-containing gas is lower than the concentration of the fluorine-containing gas introduced in the first step, and generating a plasma of the gases introduced into the reaction chamber to effect a plasma processing.

According to a fourth aspect of the present invention, there is provided an organic substance removing method of removing an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas, an oxygen-containing gas, and a hydrogen-containing gas into a reaction chamber such that the concentration of the hydrogen-containing gas is higher than the concentration of the hydrogen-containing gas introduced in the first step, and generating a plasma of the gases introduced into the reaction chamber to effect a plasma processing.

According to a fifth aspect of the present invention, there is provided an organic substance removing method of removing an organic substance having an ion-implanted region, from above a substrate by utilization of a plasma of at least an oxygen-containing gas, the method comprising:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing into a reaction chamber a gas less prone to etch an exposed surface of the substrate than the gases introduced in the first step, and generating a plasma of the gas introduced into the reaction chamber to effect a plasma processing.

According to a sixth aspect of the present invention, there is provided a method of producing a semiconductor device comprising:

the step of forming a patterned organic substance on a substrate comprising a semiconductor region;

the step of implanting ions into the semiconductor region, utilizing the organic substance as a mask; and

the organic substance removing step of removing the ion-implanted organic substance from above the substrate by utilization of a plasma of a gas containing at least oxygen,

wherein the organic substance removing step comprises:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing an oxygen-containing gas into a reaction chamber without introducing a fluorine-containing gas thereinto, and generating a plasma of the gas introduced into the reaction chamber to effect a plasma processing.

According to a seventh aspect of the present invention, there is provided a method of producing a semiconductor device comprising:

the step of forming a patterned organic substance on a substrate comprising a semiconductor region;

the step of implanting ions into the semiconductor region, utilizing the organic substance as a mask; and

an organic substance removing step of removing the ion-implanted organic substance from above the substrate by utilization of a plasma of a gas containing at least oxygen,

wherein the organic substance removing step comprises:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas and an oxygen-containing gas into a reaction chamber such that the concentration of the fluorine-containing gas is not more than 0.01 vol %, and generating a plasma of the gases introduced into the reaction chamber to effect a plasma processing.

According to an eighth aspect of the present invention, there is provided a method of producing a semiconductor device comprising:

the step of forming a patterned organic substance on a substrate comprising a semiconductor region;

the step of implanting ions into the semiconductor region, utilizing the organic substance as a mask; and

an organic substance removing step of removing the ion-implanted organic substance from above the substrate by utilization of a plasma of a gas containing at least oxygen,

wherein the organic substance removing step comprises:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas, an oxygen-containing gas, and a hydrogen-containing gas into a reaction chamber such that the concentration of the fluorine-containing gas is lower than the concentration of the fluorine-containing gas introduced in the first step, and generating a plasma of the gases introduced into the reaction chamber to effect a plasma processing.

According to a ninth aspect of the present invention, there is provided a method of producing a semiconductor device, comprising:

the step of forming a patterned organic substance on a substrate comprising a semiconductor region;

the step of implanting ions into the semiconductor region, utilizing the organic substance as a mask; and

an organic substance removing step of removing the ion-implanted organic substance from above the substrate by utilization of a plasma of a gas containing at least oxygen,

wherein the organic substance removing step comprises:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing a fluorine-containing gas, an oxygen-containing gas, and a hydrogen-containing gas into a reaction chamber such that the concentration of the hydrogen-containing gas is higher than the concentration of the hydrogen-containing gas introduced in the first step, and generating a plasma of the gases introduced into the reaction chamber to effect a plasma processing.

According to a tenth aspect of the present invention, there is provided a method of producing a semiconductor device, comprising:

the step of forming a patterned organic substance on a substrate comprising a semiconductor region;

the step of implanting ions into the semiconductor region, utilizing the organic substance as a mask; and

an organic substance removing step of removing the ion-implanted organic substance from above the substrate by utilization of a plasma of a gas containing at least oxygen,

wherein the organic substance removing step comprises:

the first step of introducing an oxygen-containing gas, a hydrogen-containing gas, and a fluorine-containing gas into a reaction chamber and generating a plasma of the gases introduced into the reaction chamber to effect a plasma processing; and

the second step of introducing into a reaction chamber a gas less prone to etch an exposed surface of the substrate than the gases introduced in the first step, and generating a plasma of the gas introduced into the reaction chamber to effect a plasma processing.

According to an eleventh aspect of the present invention, there is provided an organic substance removing apparatus for removing an organic substance having an ion-implanted region, from a substrate, comprising:

a vessel;

means for evacuating the vessel;

a gas introducing system for introducing a gas containing oxygen, hydrogen, and fluorine into the vessel;

a control device for controlling the gas introducing system; and

a power supply for supplying an electric energy for inducing a plasma of the gas introduced into the vessel,

wherein the control device sets the gas introducing system in a first mode of introducing an oxygen-containing gas, a hydrogen-containing gas, and a fluorine-containing gas into a reaction chamber and then, after lapse of a predetermined time thereafter, transfers the gas introducing system into a second mode selected from four modes of:

1) a mode of introducing an oxygen-containing gas into a reaction chamber without introducing a fluorine-containing gas thereinto;

2) a mode of introducing a fluorine-containing gas and an oxygen-containing gas into a reaction chamber such that the concentration of the fluorine-containing gas is not more than 0.01 vol %;

3) a mode of introducing a fluorine-containing gas, an oxygen-containing gas, and a hydrogen-containing gas into a reaction chamber such that the concentration of the fluorine-containing gas is lower than the concentration of the fluorine-containing gas introduced in the first mode; and

4) a mode of introducing a fluorine-containing gas, an oxygen-containing gas, and a hydrogen-containing gas such that the concentration of the hydrogen-containing gas is higher than the concentration of the hydrogen-containing gas introduced in the first mode.

According to a twelfth aspect of the present invention, there is provided an organic substance removing apparatus for removing an organic substance having an ion-implanted region, from a substrate, comprising:

a vessel;

means for evacuating the vessel;

a gas introducing system for introducing a gas containing oxygen, hydrogen, and fluorine into the vessel;

a control device for controlling the gas introducing system; and

a power supply for supplying an electric energy for inducing a plasma of the gas introduced into the vessel,

wherein the control device sets the gas introducing system in a first mode of introducing an oxygen-containing gas, a hydrogen-containing gas, and a fluorine-containing gas into a reaction chamber and then, after lapse of a predetermined time thereafter, transfers the gas introducing system into a second mode of introducing into a reaction chamber a gas less prone to etch an exposed surface of the substrate than the gases introduced into the reaction chamber in the first mode.

The fluorine-containing gas is at least one species selected from fluorine gas (F₂), nitrogen fluoride gases (NF₃ etc.), sulfur fluoride gases (SF₆, S₂F₂, SF₂, SF₄, SOF₂, etc.), carbon fluoride gases (CF₄, C₂F₆, C₄F₈, CHF₃, CH₂F₂, CH₃F, C₃F₈, etc.), and fluoride gases of rare gases (XeF etc.), whereby it becomes feasible to facilitate the modification and removal of the ion-implanted region of an organic substance and to increase the removing rate of an organic substance.

The hydrogen-containing gas is at least one species selected from hydrogen gas (H₂), and hydrogen compound gases (H₂O, CH₄, C₂H₆, C₃H₈, CH₃OH, C₂H₅OH, C₃H₇OH, etc.), whereby the surface of the substrate exposed out from the organic substance is prevented from being etched with the fluorine-containing gas.

When the density of the plasma in the first step is not less than 1×10¹¹ cm⁻³, the removing rate of an organic substance can be increased.

The heating temperature of the substrate in the first step is set to be not higher than the heating temperature of the substrate in the second step, thereby restraining the popping of an organic substance.

In the first step, fluorine is implanted from the plasma into the organic substance into which phosphorus, arsenic, or boron has been implanted, thereby modifying a surface of the organic substance.

The removal of an organic substance can be implemented with good repeatability by a method of monitoring the light emission of the plasma and transferring (or changing over) the processing from that of the first step to that of the second step, based on the result of the monitor, or by a method of measuring the elapsed time in the first step and transferring the processing from that of the first step to that of the second step, based the elapsed time.

In order to better suppress the etching of the exposed surface of the substrate, it is also preferable to arrange the method such that the processing is transferred from that of the first step to that of the second step before a region deteriorated by ion implantation is completely removed in the first step.

The first step and the second step are preferably carried out in a common reaction chamber.

The organic substance is, for example, a patterned resist.

The substrate comprises a surface comprised of at least one selected from silicon or a silicon compound, exposed out from the organic substance.

### BRIEF DESCRIPTION OF THE DRAWINGS

FIG. 1 is a schematic structural view showing an organic substance removing apparatus according to an embodiment of the present invention;

FIG. 2 is a flowchart of an organic substance removing method according to an embodiment of the present invention;

FIGS. 3A, 3B, 3C and 3D are schematic views for explaining a method of producing a semiconductor device according to an embodiment of the present invention;

FIG. 4 is a graphical representation showing the relationship between the distance (depth) from the surface of the photoresist subjected to modification, and the concentrations of fluorine and phosphorus at that depth; and

FIG. 5 is a graphical representation showing the relationship between the time taken in the first step, and the number of oxide residues on a sample obtained by carrying out the second step subsequently to the first step.

### DETAILED DESCRIPTION OF THE PREFERRED EMBODIMENTS

The embodiments of the present invention will be described below with reference to the attached drawings.

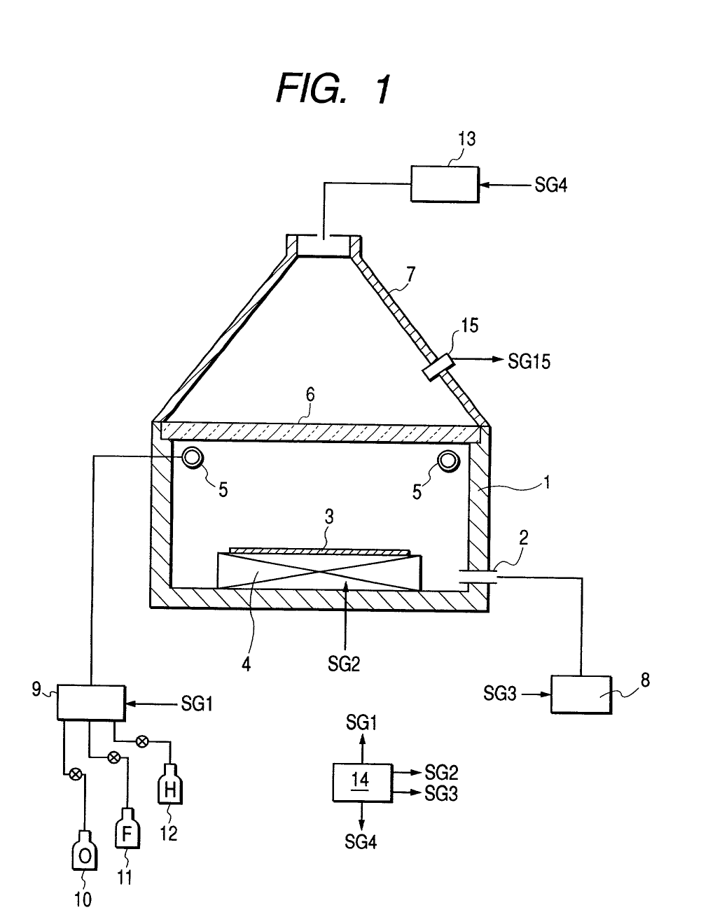

FIG. 1 is a structural view showing a removing apparatus for removing an organic substance, such as the photoresist or the like, according to an embodiment of the present invention.

The photoresist removing apparatus illustrated in FIG. 1 is arranged to be able to remove the photoresist in such a way that the portion deteriorated by ion implantation of the photoresist formed on the semiconductor substrate is firstly modified with a high density plasma of not less than 1×10¹¹ cm⁻³, specifically, of about 1×10¹² cm⁻³ generated by a high frequency power of microwaves or the like, and then the photoresist including the deteriorated portion thus modified is removed by an oxygen plasma process or the like.

The photoresist removing apparatus illustrated in FIG. 1 is provided with a vacuum vessel 1 of stainless steel or the like for defining a reaction chamber, an exhaust duct 2 for evacuating the interior of the vessel 1, a heater 4 for heating a substrate 3 placed on a support means for supporting the semiconductor substrate 3, a gas inlet tube 5 for introducing gas into the vessel 1, a dielectric port 6 for isolating the interior and exterior of the vessel from each other while transmitting the high frequency power, and a high frequency power supply 7 for supplying the high frequency power of microwaves or the like.

An exhaust system 8 including a vacuum pump, a valve, etc. is connected to the exhaust duct 2 and the gas inside the vessel 1 is evacuated through the exhaust duct 2 by activating the exhaust system.

Connected to the gas inlet tube 5 are a gas introducing system 9 including valves, flow rate controllers, etc., an oxygen-containing gas source 10, a fluorine-containing gas source 11, a hydrogen-containing gas source 12, and so on. Then, the gas introducing system 9 determines gas species to be introduced into the vessel in each step while controlling the flow rate controllers of predetermined gas lines.

To the high frequency power supply 7 is connected a high frequency power source 13 such as a microwave power source or the like.

In the present embodiment, the high frequency power supply 7 is a microwave waveguide, but it can also be either of a slot antenna and a rodlike antenna.

The high frequency power source 13 can also be either of a VHF power source, an RF power source, and so on instead of the microwave power source. In such cases, the plasma can be generated by supplying a power into the vessel by use of a rodlike antenna, a coil, an inductive coupling electrode, a capacitive coupling electrode, and so on.

The exhaust system 8, heater 4, gas introducing system 9, and high frequency power source 13 are constructed such that their operation (timing of on and off, gas flow rates, power to be supplied, supply of a high frequency power, etc.) can be controlled by control signals SG1, SG2, SG3, and SG4 supplied from a controller 14.

In the present embodiment, the vertical position of the heater 4 is set at a height where the ions in the plasma do not reach the semiconductor substrate 3 placed on the heater 4.

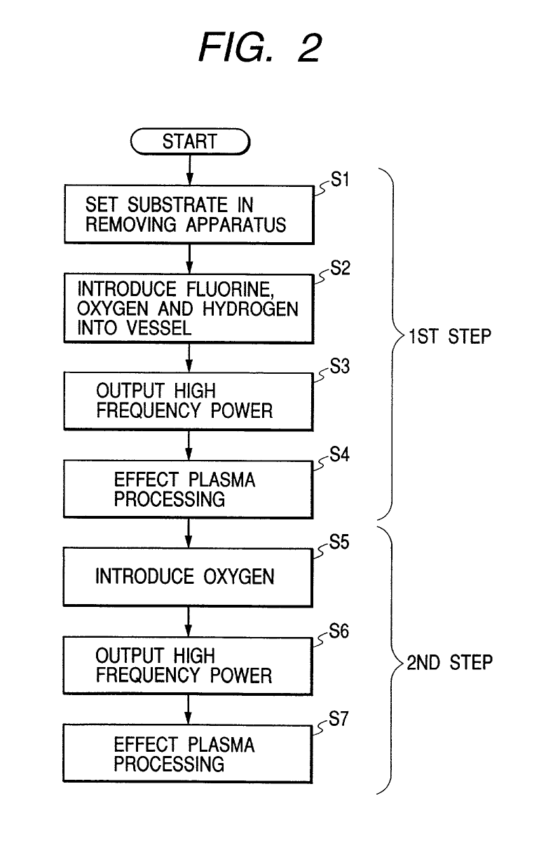

FIG. 2 is a flowchart showing a method of using the removing apparatus for removal of a photoresist illustrated in FIG. 1. The method of using the photoresist removing apparatus of FIG. 1 will be described referring to FIG. 2.

In order to allow the deteriorated portion of the photoresist to be removed with the oxygen plasma, a modification described below is first carried out in the first step.

A photoresist as an organic substance is coated on a surface of a semiconductor substrate such as a silicon wafer or the like, and then exposed in a predetermined pattern with an aligner and developed. The semiconductor substrate with the thus patterned resist of the organic substance (which does not have to be photosensitive any longer in this state) is set in an ion implanter and then ions of phosphorus, arsenic, boron, or the like are implanted thereinto. The ion implanter may be an ordinary line beam implanter or a plasma ion implanter. After preparation of the sample obtained in this way, the process illustrated in FIG. 2 is started.

The semiconductor substrate 3 with the resist including the deteriorated portion as an ashing-resistant portion due to the ion implantation is set on the heater 4 heated to, for example, about 70° C. to 180° C. This causes the heater 4 to heat the semiconductor substrate 3 to about 70° C. to 180° C. (step S1).

The appropriate heating temperature is determined depending upon the amount of ion implantation (dose), whether the resist is exposed to ultraviolet light (UV) or not, and so on. In general, the higher the temperature, the shorter the time for the modification with the high density plasma. However, in order to prevent contamination of the semiconductor substrate with the organic substance resulting from popping, it is necessary to determine the temperature in the range where the resist does not cause popping. Thus, the temperature is desirably selected in the range of not more than 100° C. herein.

In the next step, the vacuum pump of the exhaust system 8 connected to the exhaust duct 2 is activated to reduce the pressure in the vessel 1 and evacuate the inside, for example, to the pressure not more than 1.33×10⁻⁷ Pa. Then, the gas switching device 9 of the gas supply system is switched into a first mode to introduce a gas containing oxygen, hydrogen, and fluorine (for example, a mixture of a fluorine-containing gas such as SF₆, an oxygen-containing gas such as O₂, and a hydrogen-containing gas such as H₂) supplied as a gas for plasma process, through the gas inlet port 5 into the vessel 1 while exhausting, so as to maintain the interior of the vessel 1 under the pressure of about 66.5 Pa to 400 Pa (step S2).

It is recommended in this step that the concentration of the oxygen-containing gas be selected from the range of 50 vol % to 99 vol %, the concentration of the fluorine-containing gas from the range of 0.05 vol % to 5 vol %, and the concentration of the hydrogen-containing gas from the range of 0.3 vol % to 3 vol %.

It is also preferable to use an inert gas such as nitrogen, argon, helium, neon, krypton, xenon, or the like as needed, in order to control the concentration of a gas of a certain species or in order to use it as a carrier gas for the aforementioned gases.

The oxygen-containing gas can be selected from oxygen gas, and oxide gases such as nitrogen oxides and the like.

Specifically, the oxygen-containing gas can be selected from O₂, N₂O, NO₂, NO, CO₂, and so on.

The fluorine-containing gas can be selected from fluorine gas, and fluoride gases such as nitrogen fluoride, sulfur fluorides, carbon fluorides, and so on.

Specifically, the fluorine-containing gas can be selected from F₂, NF₃, SF₆, CF₄, C₂F₆, C₄F₈, CHF₃, CH₂F₂, CH₃F, C₃F₈, S₂F₂, SF₂, SF₄, SOF₂, and so on.

The hydrogen-containing gas can be selected from hydrogen gas, water, and hydride gases such as hydrocarbons and the like.

Specifically, the hydrogen-containing gas is selected from H₂, H₂O, CH₄, C₂H₆, C₃H₈, CH₃OH, C₂H₅OH, C₃H₇OH, and so on. It is recommended in the case of using hydrogen gas that it be diluted in the concentration of not more than 4 vol % with an inert gas.

Then, microwaves as high frequency power are supplied, for example, at a power of 1500 W from the high frequency power source 13 (step S3). The microwaves are supplied through the microwave waveguide and the dielectric port into the vessel 1.

When the high frequency power is supplied under the above conditions into the atmosphere filled with the oxygen-containing gas, the fluorine-containing gas, and the hydrogen-containing gas, the high density plasma of about 1×10¹² cm⁻³ is generated (step S4).

This high density plasma applies ozone, active species of oxygen, active species of fluorine, active species of hydrogen, etc. generated therein, to the surface of the resist, whereby the deteriorated region of the resist due to the ion implantation is modified. This makes it feasible to remove the resist well even by the ashing with only the oxygen-containing gas in the second step.

After lapse of a predetermined time, the supply of the high frequency power is stopped once to cease the plasma and then the process transfers to the next second step. Namely, the resist removing apparatus is switched from the first mode to the second mode by the controller 14.

The data of the time necessary for the first step can be preliminarily computed from experimental data. If it is stored in a memory of the controller 14, the controller 14 can be configured so as to terminate the first step and start the second step, based on the data.

For example, when an 8-inch semiconductor substrate 3 patterned by coating with the photoresist and development and then subjected to implantation with ions of phosphorus (P⁺) under the conditions of implantation energy of 80 keV and the dose of 1×10¹⁶ cm⁻² is modified with a high density plasma of about 1×10¹² cm⁻³, the generation time of a plasma of the mixture of oxygen, fluorine, and hydrogen necessary for the first step will be approximately 30 seconds.

Therefore, after the lapse of this generation time, the mode can be switched into the second mode to be transferred to the second step described hereinafter.

The mode switching can also be carried out based on a signal from an in-situ monitor. Namely, the mode switching is carried out in such a way that the monitor always monitors the light emission caused by CO and H as products from the resist or by 0 from the added gases and an information SG15 from the monitor is sent to the controller 14 to determine the switching time.

For example, the system may be constructed with a photodetector for detecting the plasma emission intensity as indicated by numeral 15 in FIG. 1 and arranged to measure the intensity of light at the emission peak wavelength of hydrogen atoms of 656 nm, the emission peak wavelength of oxygen atoms of 777 nm, the emission peak wavelength of CO of 309 nm, or the like, terminate the first step according to the result of the measurement, and then transfer to the second step.

The second step is a step of mainly ashing the not deteriorated portion of the photoresist with an oxygen plasma. The ashing is carried out as follows. First, while maintaining the temperature of the heater 4 and the airtight state of the vessel 1, the vessel 1 is evacuated down to an approximate vacuum by the vacuum pump of the exhaust system 8 connected to the exhaust duct 2. After that, only pure oxygen gas is introduced through the gas inlet port 5 to control the pressure in the vessel 1 to about 39.9 Pa (≅0.3 Torr) (step S5).

The next step is a step of outputting microwaves, for example, of 1500 W generated by the high frequency power source 13 (step S6). The microwaves are supplied through the microwave waveguide 7 and the dielectric port 6 into the vessel 1.

When the microwaves are incident on oxygen under the above conditions, an oxygen plasma is generated in the high density of about 1×10¹² cm⁻³ (step S7). Ozone, active species of oxygen, etc. generated by the oxygen plasma ash the modified resist and remove it from above the substrate. When the ashing is carried out under the above conditions, it can be completed in approximately 50 seconds.

In the second step, the ashing does not always have to be conducted with the oxygen plasma of only oxygen, but it may also be carried out, for example, using a mixed gas of oxygen and a fluorine-containing gas in so lower a concentration as not to corrode the semiconductor substrate than that of the gas used in the first step, or using a mixed gas of oxygen and a hydrogen-containing gas to generate hydrogen radicals in the plasma. Further, the processing may also be carried out using a mixed gas of a fluorine-containing gas, an oxygen-containing gas, and a hydrogen-containing gas.

Specifically, where a fluorine-containing gas is added in the second step, it is desirable to use either one of the following three mixed gases.

(1) A fluorine-containing gas and an oxygen-containing gas are introduced into the reaction chamber such that the concentration of the fluorine-containing gas is not more than 0.01 vol %.

(2) A fluorine-containing gas, an oxygen-containing gas, and a hydrogen-containing gas are introduced into the reaction chamber such that the concentration of the fluorine-containing gas is lower than the concentration of the fluorine-containing gas introduced in the first step. In this case, the concentration of the fluorine-containing gas does not always have to be kept not more than 0.01 vol %.

(3) A hydrogen-containing gas, together with a fluorine-containing gas and an oxygen-containing gas, is introduced into the reaction chamber such that the concentration of the hydrogen-containing gas is higher than the concentration of the hydrogen-containing gas introduced in the first step. In this case, the concentration of the fluorine-containing gas does not always have to be kept lower than the concentration thereof in the first step.

This makes it feasible to reduce the time necessary for the processing while preventing corrosion of the underlying substance.

A specific operation of the gas introducing system for transfer from the first step to the second step is simply to decrease the flow amount or stop the supply by controlling the flow rate controller of the fluorine-containing gas supply line, after extinction of the plasma in the first step.

If the heating temperature of the semiconductor substrate 3 by the heater 4 in the second step is increased, for example, to 250°, the time necessary for the ashing of the remaining resist can be reduced and the plasma generation time in the second step can be reduced even to the level of approximately 20 seconds.

The removal of the resist by this technique, however, requires an additional time for increasing the temperature of the heater 4. Therefore, the system may be altered such that in the first step the semiconductor substrate 3 is not placed on the heater 4 during generation of a plasma and is held above and apart from the heater 4 by a moving means provided on the support means and that upon transfer to the second step, the substrate 3 is moved down to be placed on the heater 4 during the generation of the plasma.

As the moving means capable of moving the semiconductor substrate 3 up and down above the heater 4, known lift pins or the like can be used.

Incidentally, in order to prevent the semiconductor substrate 103 from being corroded with ions in the plasma, it is necessary to determine the position of the semiconductor substrate 103 moved up by the moving means within the range up to a location at which only neutral radicals exist and which the ions in the plasma do not reach.

Further, considering the existence of the time necessary for raising the heater temperature, it can also be contemplated to provide some measures for decreasing the total time necessary for completion of the removal of resist.

For example, two apparatuses of the structure illustrated in FIG. 1 are set adjacent to each other, one being dedicated to the first step while the other to the second step. Using the apparatuses, the substrate 3 subjected to the processing at the low temperature in the first step is transferred into the other vessel, and the ashing is carried out therein while the substrate 3 subjected to the first step is placed on the heater 4 already heated to 250° C.

(Method of Producing Semiconductor Device)

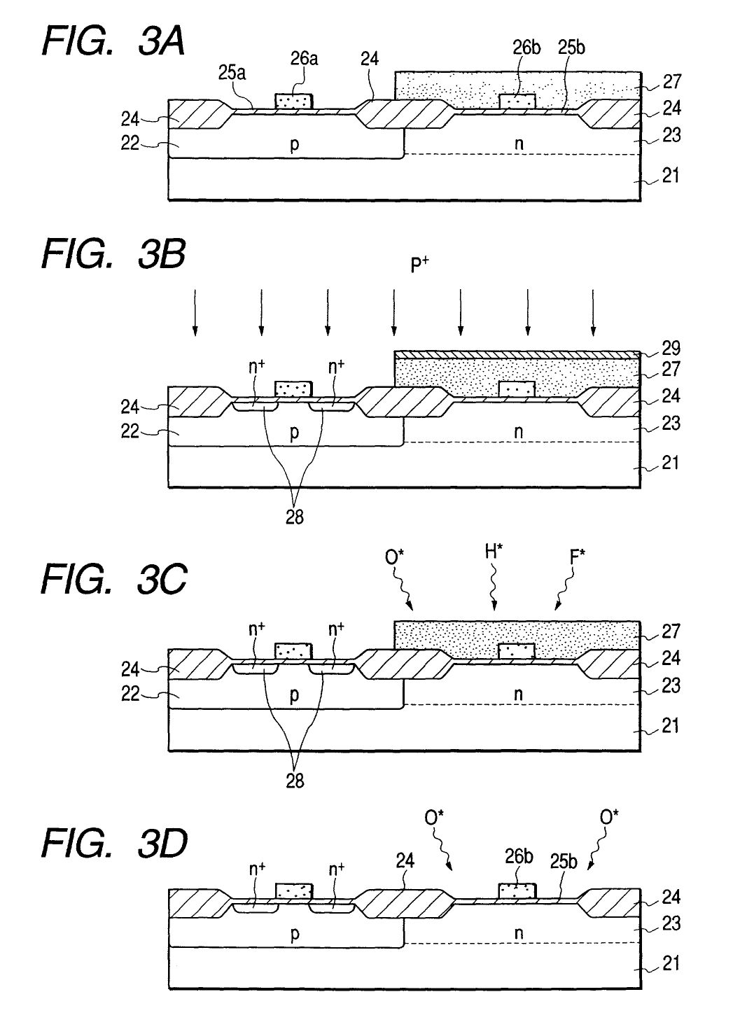

A method of producing a semiconductor device according to an embodiment of the present invention will be described with reference to FIGS. 3A to 3D.

An n-type semiconductor substrate 21 such as a silicon wafer or the like is provided and an n-type semiconductor layer 23 is epitaxially grown on the surface thereof. A p-type dopant such as boron is then made to diffuse thereinto to form a p-well 22 comprised of a p-type semiconductor. Then, isolation regions 24 comprised of silicon oxide are formed by selective oxidation. The surface of silicon is subjected to thermal oxidation to form gate oxide films 25a, 25b, and thereafter polycrystal silicon is deposited and patterned to form polycrystal silicon gate electrodes 26a, 26b. Then, a photoresist is applied, exposed, and developed, thereby forming a patterned resist 27.

The structure illustrated in FIG. 3A is obtained in this way.

Ions of phosphorus, arsenic, or the like are implanted into the structure to form source/drain regions 28 comprised of an n-type semiconductor in regions exposed out from the resist 27. A region 29 deteriorated by the ion implantation is formed on the front surface side of the resist 27.

This yields the structure illustrated in FIG. 3B.

If during the ion implantation the substrate surface is inclined and the wafer is rotated, the deteriorated region will also be formed on the side wall of the resist 27.

Then, the resist is modified by effecting the plasma processing with the oxygen-, hydrogen-, and fluorine-containing gases according to the same step as the first step described above. The region deteriorated by the ion implantation may be removed at the same time as this processing or may be only modified without being removed.

This yields the structure with n-channel MOS illustrated in FIG. 3C.

Then, the process transfers to the second step to effect the plasma processing with oxygen gas to remove the remaining resist. Since the implanted ion species of phosphorus, arsenic, or the like turn into fluoride or hydrides to disappear in the first step, there appears no residue of the implanted ion species.

Further, it is also possible to fabricate a p-channel MOS by carrying out the steps similar to FIGS. 3A to 3D, in such a manner as to cover the n-channel MOS portion with a resist and replace the implanted ion species with boron.

According to the present embodiment, the ion-implanted resist can be removed well and rapidly without over etching of the gate electrode of polycrystal silicon and the film comprised of silicon oxide on the source/drain regions.

(Experiment 1)

An 8-inch silicon wafer with an oxidized surface was prepared and coated with a photoresist for the i-line comprising the phenol novolak resin as a main component. Then, the photoresist was exposed to the i-line and baked to form a resist film of 1 μm thickness. Ions of phosphorus (P⁺) were implanted into the resist under the implantation conditions of implantation energy of 80 keV and the dose of 1×10¹⁶ cm⁻², thereby making Sample 1.

The above sample was placed on the heater heated in the vessel, the sample was heated to 100° C., and the interior of the vessel was evacuated. Oxygen gas was introduced at a flow rate of 2100 SCCM, SF₆ gas at a flow rate of 3 SCCM, and hydrogen gas diluted in 4 vol % with argon gas at a flow rate of 900 SCCM into the vessel. While the interior of the vessel was maintained under the pressure of 133 Pa, microwaves of a frequency of 2.45 GHz and a power of 1500 W was supplied to generate a plasma of the mixed gas for 40 seconds.

The depth profiles of phosphorus and fluorine in the resist of the sample subjected to the above processing were analyzed by secondary ion mass spectrometry (SIMS).

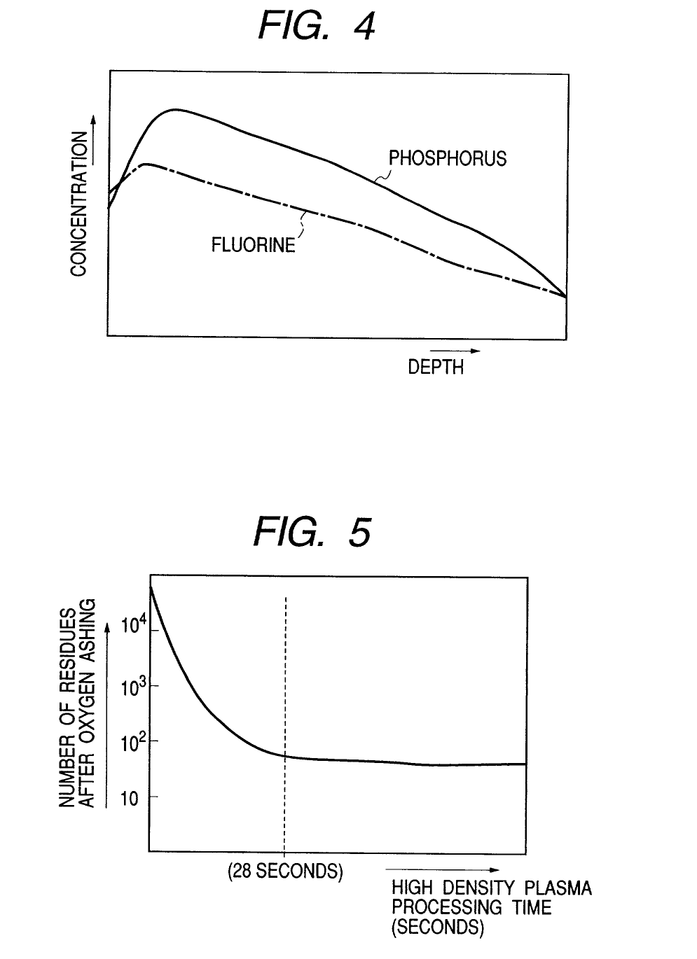

The results are presented in FIG. 4.

The obtained depth profiles of phosphorus and fluorine each had a peak concentration near the surface.

It is seen from these results that the remaining resist also contains fluorine incorporated from the fluorine plasma, in addition to preliminarily ion-implanted phosphorus, and therefore that the ion-implanted resist is modified. This suggests that the modification caused phosphorus as an implanted ion component to be coupled with fluorine within the resist.

Namely, it is considered that when fluorine is coupled with phosphorus as the implanted ion component by the modification, there occurs cleavage of crosslinkings between phenol rings of the resist component and that carrying out the second step with the oxygen plasma thereafter permits the ion component to be removed in the form of volatile fluorides during the ashing.

With the modification of the resist in this way, the ashing of the remaining resist can be effected at a sufficiently high speed with use of a less amount of fluorine or without use of fluorine in the subsequent second step.

### EXAMPLE 1

A number of Samples 2 (substrates with an ion-implanted resist) were prepared according to the same procedures and under the same conditions as in Experiment 1.

One of above Samples 2 was placed on the heater heated in the vessel and heated to 100° C., and the interior of the vessel was evacuated. Oxygen gas was introduced at a flow rate of 2100 SCCM, SF₆ gas at a flow rate of 3 SCCM, and hydrogen gas diluted in 4 vol % with argon gas at a flow rate of 900 SCCM into the vessel. While the interior of the vessel was maintained under the pressure of 133 Pa, microwaves of a frequency of 2.45 GHz and a power of 1500 W were supplied to generate a plasma of the mixed gas for 28 seconds (the first step).

After that, the mode was switched by the controller and the gas introducing system, the supply of SF₆ gas and hydrogen gas was stopped, and the plasma of oxygen gas was generated without any change in the pressure and the substrate temperature (the second step).

When the plasma emission intensity due to the resist components was reduced to become approximately constant, the supply of microwaves was terminated to cease the plasma.

Then, the sample was taken out of the vessel.

Samples 2 were processed as described above with variations in the plasma generation time in the first step in the range of 0 (without the first step) to 80 seconds.

The results are presented in FIG. 5.

FIG. 5 is a graphical representation showing the relationship between the plasma generation time (modification time) in the first step and the number of oxide residues on the semiconductor substrate subjected to the ashing subsequently to the modification.

As shown in FIG. 5, for example, during the period of the time for the modification up to 28 seconds, the number of oxide residues of sizes of not less than 0.2 μm on the semiconductor substrate exponentially decrease according to the modification time, for example, from approximately 1×10⁴ to approximately 1×10². In FIG. 5, the ordinate indicates the number of oxide residues in terms of natural logarithm.

On the other hand, with the modification time exceeding 28 seconds, there is no appreciable change in the number of oxide residues on the semiconductor substrate. It is, therefore, not preferable to set the modification time so as to exceed 28 seconds, because portions without formation of the resist of the semiconductor substrate are corroded.

In the above-stated example, in the case where the semiconductor substrate as an object to be processed, the various conditions of the resist, the heating conditions by the heater, etc. were the same, repeatability was seen in the correlation between the modification time in the first step and the number of the oxide residues on the semiconductor substrate subjected to the ashing with the oxygen plasma in the second step subsequently to the modification.

### EXAMPLE 2

An 8-inch silicon wafer with an oxidized surface was prepared and coated with a photoresist for the i-line. Then, the resist was exposed to the i-line, developed, and baked. Into the thus patterned resist were implanted ions of phosphorus (P⁺) under the conditions of an implantation energy of 80 keV and a dose of 1×10¹⁶ cm⁻², thus making Sample 3.

Then, the above sample was placed on the heater heated in the vessel and heated to 100° C., while the interior of the vessel was evacuated. Oxygen gas was introduced at a flow rate of 2100 SCCM, SF₆ gas at a flow rate of 3 SCCM, and hydrogen gas diluted in 4 vol % with argon gas at a flow rate of 900 SCCM into the vessel. While the interior of the vessel was maintained under the pressure of 133 Pa, microwaves of a frequency of 2.45 GHz and a power of 1500 W were supplied to generate a plasma of the mixed gas for 40 seconds.

The gas introducing system was controlled by the controller to stop the supply of SF₆ gas. While maintaining the temperature of the substrate and the pressure at those in the first step, the microwaves were supplied in the same manner as in the first step to generate a plasma of the mixed gas of oxygen and hydrogen for 100 to 120 seconds.

As a consequence, the average number of residues of sizes of not less than 0.2 μm on the substrate after the processing, obtained for a number of Samples 3 was 50.

The portions without formation of the resist of the semiconductor substrate were etched only in the thickness of not more than 0.1 nm.

As described above, the resist removing methods of the present invention modify the deteriorated portion of the resist partly deteriorated by the ion implantation, by utilization of the plasma of the gas containing a small amount of the fluorine-containing gas added to the oxygen-containing gas. Since the hydrogen-containing gas is added at this time, the portions exposed out from the resist can be prevented from being corroded by etching.

After that, the plasma processing is carried out by further reducing the concentration of a fluorine-containing gas to be not more than 0.01 vol %, by use of oxygen gas without using a fluorine-containing gas, by adding a hydrogen-containing gas while reducing a fluorine-containing gas, or by increasing the concentration of a hydrogen-containing gas, whereby the remaining resist thus modified is removed almost perfectly from the semiconductor substrate.

In this way, the ion-implanted resist can be removed well by ashing while suppressing the corrosion of the surface of the semiconductor substrate exposed out from the resist.

What is claimed is:

1. An organic substance removing method of removing an organic substance having an ion-implanted region, from above a substrate by utilization of a plasma of at least an oxygen-containing gas, the method comprising:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing an oxygen-containing gas into a reaction chamber without introducing a fluorine-containing gas thereinto, and generating a plasma of the gas introduced into the reaction chamber to effect a plasma processing.

2. An organic substance removing method of removing an organic substance having an ion-implanted region, from above a substrate by utilization of a plasma of at least an oxygen-containing gas, the method comprising:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas and an oxygen-containing gas into a reaction chamber such that the concentration of the fluorine-containing gas is not more than 0.01 vol %, and generating a plasma of the gases introduced into the reaction chamber to effect a plasma processing.

3. An organic substance removing method of removing an organic substance having an ion-implanted region, from above a substrate by utilization of a plasma of at least an oxygen-containing gas, the method comprising:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas, an oxygen-containing gas, and a hydrogen-containing gas into a reaction chamber such that the concentration of the fluorine-containing gas is lower than the concentration of the fluorine-containing gas introduced in the first step, and generating a plasma of the gases introduced into the reaction chamber to effect a plasma processing.

4. An organic substance removing method of removing an organic substance having an ion-implanted region, from above a substrate by utilization of a plasma of at least an oxygen-containing gas, the method comprising:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas, an oxygen-containing gas, and a hydrogen-containing gas into a reaction chamber such that the concentration of the hydrogen-containing gas is higher than the concentration of the hydrogen-containing gas introduced in the first step, and generating a plasma of the gases introduced into the reaction chamber to effect a plasma processing.

5. An organic substance removing method of removing an organic substance having an ion-implanted region, from above a substrate by utilization of a plasma of at least an oxygen-containing gas, the method comprising:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing into a reaction chamber a gas less prone to etch an exposed surface of the substrate than the gases introduced in the first step, and generating a plasma of the gas introduced into the reaction chamber to effect a plasma processing.

6. The organic substance removing method according to any one of claims 1 to 5, wherein the fluorine-containing gas comprises at least one selected from fluorine gas, a nitrogen fluoride gas, a sulfur fluoride gas, and a carbon fluoride gas.

7. The organic substance removing method according to any one of claims 1 to 5, wherein the hydrogen-containing gas comprises at least one selected from hydrogen gas and a gas of a hydrogen compound.

8. The organic substance removing method according to any one of claims 1 to 5, wherein the density of the plasma in the first step is not less than 1×10¹¹ cm⁻³.

9. The organic substance removing method according to any one of claims 1 to 5, wherein the heating temperature of the substrate in the first step is not higher than the heating temperature of the substrate in the second step.

10. The organic substance removing method according to any one of claims 1 to 5, wherein in the first step, fluorine is implanted from the plasma into the organic substance having phosphorus, arsenic or boron implanted thereinto, to effect modification of a surface of the organic substance.

11. The organic substance removing method according to any one of claims 1 to 5, wherein the light emission from the plasma is monitored and the processing is transferred from that of the first step to that of the second step, based thereon.

12. The organic substance removing method according to any one of claims 1 to 5, wherein the elapsed time in the first step is measured and the processing is transferred from that of the first step to that of the second step, based thereon.

13. The organic substance removing method according to any one of claims 1 to 5, wherein before a region deteriorated by ion implantation is completely removed in the first step, the processing is transferred from that of the first step to that of the second step.

14. The organic substance removing method according to any one of claims 1 to 5, wherein the first step and the second step are carried out in a common reaction chamber.

15. The organic substance removing method according to any one of claims 1 to 5, wherein the organic substance is a patterned resist.

16. A method of producing a semiconductor device, comprising:
the step of forming a patterned organic substance on a substrate comprising a semiconductor region;
the step of implanting ions into the semiconductor region, utilizing the organic substance as a mask; and
the organic substance removing step of removing the ion-implanted organic substance from above the substrate by utilization of a plasma of a gas containing at least oxygen,
wherein the organic substance removing step comprises:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing an oxygen-containing gas into a reaction chamber without introducing a fluorine-containing gas thereinto, and generating a plasma of the gas introduced into the reaction chamber to effect a plasma processing.

17. A method of producing a semiconductor device, comprising:
the step of forming a patterned organic substance on a substrate comprising a semiconductor region;
the step of implanting ions into the semiconductor region, utilizing the organic substance as a mask; and
an organic substance removing step of removing the ion-implanted organic substance from above the substrate by utilization of a plasma of a gas containing at least oxygen,
wherein the organic substance removing step comprises:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas and an oxygen-containing gas into a reaction chamber such that the concentration of the fluorine-containing gas is not more than 0.01 vol %, and generating a plasma of the gases introduced into the reaction chamber to effect a plasma processing.

18. A method of producing a semiconductor device, comprising:
the step of forming a patterned organic substance on a substrate comprising a semiconductor region;
the step of implanting ions into the semiconductor region, utilizing the organic substance as a mask; and
an organic substance removing step of removing the ion-implanted organic substance from above the substrate by utilization of a plasma of a gas containing at least oxygen,
wherein the organic substance removing step comprises:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas, an oxygen-containing gas, and a hydrogen-containing gas into a reaction chamber such that the concentration of the fluorine-containing gas is lower than the concentration of the fluorine-containing gas introduced in the first step, and generating a plasma of the gases introduced into the reaction chamber to effect a plasma processing.

19. A method of producing a semiconductor device, comprising:
the step of forming a patterned organic substance on a substrate comprising a semiconductor region;
the step of implanting ions into the semiconductor region, utilizing the organic substance as a mask; and
an organic substance removing step of removing the ion-implanted organic substance from above the substrate by utilization of a plasma of a gas containing at least oxygen,
wherein the organic substance removing step comprises:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing a fluorine-containing gas, an oxygen-containing gas, and a hydrogen-containing gas into a reaction chamber such that the concentration of the hydrogen-containing gas is higher than the concentration of the hydrogen-containing gas introduced in the first step, and generating a plasma of the gases introduced into the reaction chamber to effect a plasma processing.

20. A method of producing a semiconductor device, comprising:
the step of forming a patterned organic substance on a substrate comprising a semiconductor region;
the step of implanting ions into the semiconductor region, utilizing the organic substance as a mask; and
an organic substance removing step of removing the ion-implanted organic substance from above the substrate by utilization of a plasma of a gas containing at least oxygen,
wherein the organic substance removing step comprises:
the first step of introducing an oxygen-containing gas, a hydrogen-containing gas, and a fluorine-containing gas into a reaction chamber and generating a plasma of the gases introduced into the reaction chamber to effect a plasma processing; and
the second step of introducing into a reaction chamber a gas less prone to etch an exposed surface of the substrate than the gases introduced in the first step, and generating a plasma of the gas introduced into the reaction chamber to effect a plasma processing.

21. The method according to any one of claims 16 to 20, wherein the fluorine-containing gas comprises at least one selected from fluorine gas, a nitrogen fluoride gas, a sulfur fluoride gas, and a carbon fluoride gas.

22. The method according to any one of claims 16 to 20, wherein the hydrogen-containing gas comprises at least one selected from hydrogen gas and a gas of a hydrogen compound.

23. The method according to any one of claims 16 to 20, wherein the density of the plasma in the first step is not less than 1×10¹¹ cm⁻³.

24. The method according to any one of claims 16 to 20, wherein the heating temperature of the substrate in the first step is not higher than the heating temperature of the substrate in the second step.

25. The method according to any one of claims 16 to 20, wherein in the first step, fluorine is implanted from the plasma into the organic substance having phosphorus, arsenic or boron implanted thereinto, to effect modification of a surface of the organic substance.

26. The method according to any one of claims 16 to 20, wherein the light emission from the plasma is monitored and the processing is transferred from that of the first step to that of the second step, based thereon.

27. The method according to any one of claims 16 to 20, wherein the elapsed time in the first step is measured and the processing is transferred from that of the first step to that of the second step, based thereon.

28. The method according to any one of claims 16 to 20, wherein before a region deteriorated by ion implantation is completely removed in the first step, the processing is transferred from that of the first step to that of the second step.

29. The method according to any one of claims 16 to 20, wherein the first step and the second step are carried out in a common reaction chamber.

30. The method according to any one of claims 16 to 20, wherein the organic substance is a resist comprised of a photosensitive resin.

31. The method according to any one of claims 16 to 20, wherein the substrate comprises a surface comprised of at least one selected from silicon or a silicon compound, exposed out from the organic substance.

32. An organic substance removing apparatus for removing an organic substance having an ion-implanted region, from a substrate, comprising:
a vessel;
means for evacuating the vessel;
a gas introducing system for introducing a gas containing oxygen, hydrogen, and fluorine into the vessel;
a control device for controlling the gas introducing system; and
a power supply for supplying an electric energy for inducing a plasma of the gas introduced into the vessel,
wherein the control device sets the gas introducing system in a first mode of introducing an oxygen-containing gas, a hydrogen-containing gas, and a fluorine-containing gas into a reaction chamber and then, after lapse of a predetermined time thereafter, transfers the gas introducing system into a second mode selected from four modes of:
1) a mode of introducing an oxygen-containing gas into a reaction chamber without introducing a fluorine-containing gas thereinto;
2) a mode of introducing a fluorine-containing gas and an oxygen-containing gas into a reaction chamber such that the concentration of the fluorine-containing gas is not more than 0.01 vol %;
3) a mode of introducing a fluorine-containing gas, an oxygen-containing gas, and a hydrogen-containing gas into a reaction chamber such that the concentration of the fluorine-containing gas is lower than the concentration of the fluorine-containing gas introduced in the first mode; and
4) a mode of introducing a fluorine-containing gas, an oxygen-containing gas, and a hydrogen-containing gas such that the concentration of the hydrogen-containing gas is higher than the concentration of the hydrogen-containing gas introduced in the first mode.

33. An organic substance removing apparatus for removing an organic substance having an ion-implanted region, from a substrate, comprising:
a vessel;
means for evacuating the vessel;
a gas introducing system for introducing a gas containing oxygen, hydrogen, and fluorine into the vessel;
a control device for controlling the gas introducing system; and
a power supply for supplying an electric energy for inducing a plasma of the gas introduced into the vessel,
wherein the control device sets the gas introducing system in a first mode of introducing an oxygen-containing gas, a hydrogen-containing gas, and a fluorine-containing gas into a reaction chamber and then, after lapse of a predetermined time thereafter, transfers the gas introducing system into a second mode of introducing into a reaction chamber a gas less prone to etch an exposed surface of the substrate than the gases introduced in the first mode.
